(19) United States
(12) Patent Application Publication
(10) Pub. No.: US 2013/0014817 A1
(43) Pub. Date: Jan. 17, 2013

(54) CONDUCTIVE PASTE FOR SOLAR CELL ELECTRODES, METHOD FOR THE MANUFACTURE OF SOLAR CELL ELECTRODES

(71) Applicant: Takuya Konno, Kanagawa (JP)

(72) Inventor: Takuya Konno, Kanagawa (JP)

(73) Assignee: E.I. DU PONT DE NEMOURS AND COMPANY, Wilmington, DE (US)

(21) Appl. No.: 13/183,755

(22) Filed: Jul. 15, 2011

(51) Int. Cl. H01L 31/0224; H01L 31/18; H01B 1/12

(52) U.S. Cl. 136/256; 252/519.21; 438/98; 257/E31.124

(57) ABSTRACT

A conductive paste for forming a solar cell electrode, comprising: a conductive powder; a glass frit; a metal resinate wherein a metal contained in the metal resinate is 0.15 to 1 parts by weight based on 100 parts by weight of the conductive powder; and an organic medium.

### BACKGROUND OF THE INVENTION

1. Field of the Invention

The present invention relates to a solar cell. More specifically, it relates to an electrode of solar cell formed by using a conductive paste.

2. Description of Related Art

In order to increase power generation characteristics of a solar cell, an electrical property of a solar cell electrode is required to be improved. For example, by decreasing resistance of an electrode, the power generation efficiency could increases. US patent publication Number US2007/0187652, which is incorporated herein by reference, discloses a conductive paste for a solar cell electrode contains organic binder, conductive particle, glass frits, metal resinate as sintering inhibitor. The metal resinate can comprise a metal of manganese, titanium, bismuth, zinc, palladium, platinum, zirconia, boron, barium, aluminum, copper, gold, indium, iron, nickel, ruthenium, rhodium, silicon, silver or tin with content of 0.002-0.05 weight percent based on the total weight of the conductive paste.

### BRIEF SUMMARY OF THE INVENTION

An objective of the present invention is to provide a conductive paste that can render a solar cell electrode good electrical property, for example contact resistance between an electrode and a semiconductor substrate, and to provide a solar cell that has an electrode formed from the conductive paste.

An aspect of the invention relates to a method for manufacturing a solar cell electrode, comprising; applying onto a semiconductor substrate a conductive paste comprising a conductive powder, a glass frit, a metal resinate comprising, based on 100 parts by weight of the conductive powder, 0.08 to 1 parts by weight of a metal selected from the group consisting of lead (Pb), barium (Ba), calcium (Ca), bismuth (Bi), and a mixture thereof, and an organic medium; and firing the conductive paste.

Another aspect of the invention relates to a conductive paste for forming a solar cell electrode, comprising a conductive powder, a glass frit, a metal resinate comprising, based on 100 parts by weight of the conductive powder, 0.08 to 1 parts by weight of a metal selected from the group consisting of lead (Pb), barium (Ba), calcium (Ca), bismuth (Bi), and a mixture thereof, and a organic medium.

Another aspect of the invention relates to a solar cell electrode formed on the semiconductor substrate, wherein the electrode, prior to the firing, comprises the above conductive paste.

A solar cell electrode formed with the present invention can obtain a superior electrical characteristic such as contact resistance between the electrode and a semiconductor substrate.

### BRIEF DESCRIPTION OF THE DRAWINGS

FIG. 1A to 1F are drawings for explaining a solar cell electrode production process.

FIG. 2 illustrates shape of a test sample for measuring contact resistance (Rc) of electrodes formed on an silicon substrate in Example.

FIG. 3 is a conceptual diagram of Rc calculation in Example.

### DETAILED DESCRIPTION OF THE INVENTION

A conductive paste for a solar cell electrode of the present invention includes a conductive powder, a lead resinate, and an organic medium. The conductive paste is described below as well as a method of manufacturing a solar cell electrode made of the conductive paste.

### (Conducting Powder)

The conductive powder is a metal powder to transport electrical current in an electrode.

In an embodiment, conductive powder can be a metal powder having an electrical conductivity 1.00×10⁷ Siemens (S)/m or more at 293 Kelvin. Such conductive metal is, for example, iron (Fe; 1.00×10⁷ S/m), aluminum (Al; 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), molybdenum (Mo; 2.10×10⁷ S/m), magnesium (Mg; 2.30×10⁷ S/m), tungsten (W; 1.82×10⁷ S/m), cobalt (Co; 1.46×10⁷ S/m) and zinc (Zn; 1.64×10⁷ S/m). In an embodiment, the mixture of the conductive powder is used.

In another embodiment, conductive powder is a metal powder having electrical conductivity 3.00×10⁷ S/m or more at 293 Kelvin. The conductive powder can be one or more metal powder selected from the group consisting of Al, Cu, Ag and Au. Using such conductive metal powder having relatively high electrical conductivity, electrical property of a solar cell could be further improved.

In an embodiment, the conductive powder can be flaky or spherical in shape. There is no special restriction on particle diameter of the conductive powder from a viewpoint of a technological effectiveness when used as typical electrically conducting paste. However, since the particle diameter affects the sintering characteristics of conductive powder, for example, large silver particles are sintered more slowly than silver particles of small particle diameter, the diameter can be 0.1 to 10.0 μm. Furthermore, it is also necessary that the conductive powder has the particle diameter appropriate for the method used to coat the electrically conducting paste on a semiconductor substrate (for example, screen printing). In the present invention, it is possible to mix two or more types of conductive powder of different diameters.

In an embodiment, the conductive powder is of ordinary high purity (99%). However, depending on the electrical requirements of the electrode pattern, less pure silver can also be used.

There are no special restrictions on the content of the conductive powder, however, in an embodiment, the conductive powder can be 40 to 90 weight percent (wt %) based on the total weight of the conductive paste.

### (Metal Resinate)

The metal resinate is a component composed of one or more of organic constituent and one or more of metal. The metal resinate can be dispersed uniformly in a paste. This property is especially beneficial when the conductive paste needs just a small quantity of a metal. When a metal is added to a past at a small amount, the metal tends to aggregate, resulting in an uneven dispersion. However a metal in the metal resinate can disperse uniformly in a conductive paste even if the amount of the metal is very small.

The metal resinate comprises a metal selected from the group consisting of lead (Pb), barium (Ba), calcium (Ca), bismuth (Bi), and a mixture thereof.

The metal resinate can be expressed by the following general formula (I), for example.

Me(XR)ₙ (I)

In the above formula, Me stands for a metal selected from the group consisting of lead (Pb), barium (Ba), calcium (Ca), bismuth (Bi), and a mixture thereof. These metal in the metal resinate can decrease contact resistance as shown in Example below.

X stands for direct binding, —O(CO)—, —(CO)O—, —CO—, —S—, or —SO₃—. R stands for a linear, branched or cyclic hydrocarbon having 1 to 10 carbon atoms.

In an embodiment, the hydrocarbon of the metal resinate can be selected from the group consisting of methyl, ethyl, n-propyl, isopropyl, cyclopropyl, n-butyl, isobutyl, t-butyl, cyclobutyl, n-pentyl, cyclopentyl and other pentyl groups, n-hexyl, cyclohexyl and other hexyl groups, n-heptyl and other heptyl groups, n-octyl and other octyl groups, n-nonyl and other nonyl groups, and n-decyl and other decyl groups. n is 1, 2 or 3.

These metal resinates are liquid or solid at normal temperature, and can be incorporated into the conductive paste as they are, but these can also be dissolved or dispersed in a solvent such as toluene, ethanol, acetylacetone or methylene chloride, and used.

In an embodiment of the present invention, the maximum content of metal resinate can be 20 parts by weight, in another embodiment, 15 parts by weight, in another embodiment 10 parts by weight, in another embodiment 8 parts by weight, based on 100 parts by weight of the conductive powder. The minimum content of metal resinate can be 0.2 parts by weight, in another embodiment, 0.6 parts by weight, in another embodiment, 1.0 parts by weight, based on 100 parts by weight of the conductive powder. Within the range, contact resistance of a solar cell electrode can be improved as shown in Example below.

In an embodiment, the metal in the metal resinate can be 1 to 50 wt %, in another embodiment, 2 to 37 wt %, in another embodiment, 2 to 30 wt %, in another embodiment, 4 to 28 wt %, based on the weight of the metal resinate. Within the range of the content, the metal resinate can disperse uniformly in a paste.

In an embodiment, the maximum content of the metal contained in the metal resinate can be 1 parts by weight, in another embodiment, 0.8 parts by weight, in another embodiment, 0.5 parts by weight, based on 100 parts by weight of the conductive powder. In another embodiment, the minimum content of the metal contained in the metal resinate can be 0.15 parts by weight, in another embodiment, 0.19 parts by weight, in another embodiment, 0.23 parts by weight, in another embodiment, 0.26 parts by weight, based on 100 parts by weight of the conductive powder. Within the range of the content, the metal can reduce contact resistance of the solar cell electrode as shown in Example below.

In an embodiment, the metal resinate can be a lead (Pb) resinate. In another embodiment, the lead resinate can be selected from the group consisting of 2-ethylhexyl acid lead, lead stearate, lead laurate, lead ricinoleic acid, lead naphthenate and a mixture thereof. In another embodiment, the lead resinate can be 2-ethylhexyl acid lead. The structural formula of 2-ethylhexyl acid lead is shown below.

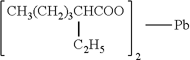

In an embodiment, the metal resinate can be a barium (Ba) resinate. In another embodiment, the barium resinate can be selected from the group consisting of ethylhexyl acid barium, barium stearate, barium laurate, barium ricinoleic acid, barium naphthenate and a mixture thereof. In another embodiment, the barium resinate can be barium laurate. The structural formula of barium laurate as an example of the barium laurate is shown below.

Ba[CH₃(CH₂)₁₀COO]₂

In an embodiment, the metal resinate can be a calcium (Ca) resinate. In another embodiment, the calcium resinate can be selected from the group consisting of ethylhexyl acid calcium, calcium stearate, calcium laurate, calcium ricinoleic acid, calcium naphthenate and a mixture thereof. In another embodiment, the calcium resinate can be 2-ethylhexyl acid calcium. The structural formula of 2-ethylhexyl acid calcium is shown below.

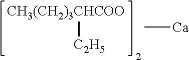

In an embodiment, the metal resinate can be a bismuth (Bi) resinate. In another embodiment, the bismuth resinate can be selected from the group consisting of ethylhexyl acid bismuth, a bismuth stearate, a bismuth laurate, bismuth ricinoleic acid, a bismuth naphthenate and a mixture thereof. In another embodiment, the bismuth resinate can be 2-ethylhexyl acid bismuth. The structural formula of 2-ethylhexyl acid bismuth is shown below.

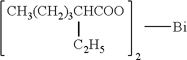

### (Glass Frit)

In an embodiment, glass frit in the conductive paste described herein promotes “fire-through” that is to penetrate a passivation layer formed on surface of a semiconductor substrate to get an electrode contact with the semiconductor substrate as well as promote sintering of the conductive powder. In addition, glass frit also facilitates binding of an electrode to the substrate.

In an embodiment, the conducting paste contains glass frit as an inorganic binder. In an embodiment, the glass frit has a softening point of 300 to 600° C. since the conductive paste is typically fired at 500 to 1000° C. Ideally, the lower softening point is more preferable to enable the firing at lower temperature, resulting in less damage on a semiconductor substrate. When the softening point is in the range, a sufficient flow of melt may occur during firing, resulting in sufficient adhesion.

In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is on glass transition temperature (Tg), the second evolution peak is on glass softening point (Ts), the third evolution peak is on crystallization point. When a glass frit is a noncrystalline glass, the crystallization point would not appear in DTA.

The chemical composition of the glass frit is not limited in the present invention. Any glass frit suitable for use in electrically conducting pastes for electronic materials is acceptable. For example, a lead borosilicate (Pb—B—Si) glass and so on can be used. Lead silicate (Pb—Si) and lead borosilicate (Pb—B—Si) glasses are excellent materials in the present invention from a viewpoint of both the range of the softening point and the glass fusion characteristics. In addition, zinc borosilicate (Zn—B—Si) or other lead-free glasses can be used.

In an embodiment, the glass frit can be 2 to 10 parts by weight, in another embodiment, 3 to 9 parts by weight, in another embodiment, 4 to 7 parts by weight, based on 100 parts by weight of the conductive powder. When the glass frit content in the conductive paste is in the range, adhesion and sintering of the conductive powder can be sufficient resulting in a preferable electrode property.

### (Organic Medium)

The electrically conductive paste in the present invention contains a organic medium. The inorganic components such as conductive powder is dispersed in the organic medium, for example, by mechanical mixing to form viscous compositions called “pastes”, having suitable consistency and rheology for printing. A wide variety of inert viscous materials can be used as an organic medium.

In the present specifications document, the “organic medium” contains polymer as resin. If the viscosity is high, solvent can be added to the organic medium to adjust the viscosity.

In the present invention, any organic medium can be used, for example a pine oil solution or an ethylene glycol monobutyl ether monoacetate solution of a resin (polymethacrylate or the like) or ethyl cellulose, a terpineol solution of ethyl cellulose, etc. In the present invention, it is preferable to use the terpineol solution of ethyl cellulose (ethyl cellulose content=5 wt % to 50 wt %). A solvent containing no polymer, for example, water or an organic liquid can be used as a viscosity-adjusting agent. Among the organic liquids that can be used are alcohols, alcoholesters (for example, acetate or propionate), and terpenes (such as pine oil, terpineol or the like). The content of the organic medium is preferably 10-50 wt % of the weight of the electrically conducting paste.

### (Additives)

Thickener, stabilizer or surfactant as additives may be added to the conductive paste of the present invention. Other common additives such as a dispersant, viscosity-adjusting agent, and so on can also be added. The amount of the additive depends on the desired characteristics of the resulting electrically conducting paste and can be chosen by people in the industry. The additives can also be added in multiple types.

### (Zinc Oxide Powder)

In the present invention, zinc oxide (ZnO) powder is not an essential component. However, it can be added as need arises. ZnO powder in a conductive paste can have a function to reduce series resistance of an electrode in combination with glass frit.

In an embodiment, ZnO powder is 0.5-37 parts by weight based on 100 parts by weight of the conductive powder. In other embodiment, ZnO powder is not more than 18 parts by weight based on 100 parts by weight of the conductive powder. In further other embodiment, ZnO powder is not more than 8 parts by weight based on 100 parts by weight of the conductive powder.

In an embodiment, ZnO powder has an average particle size in the range of 10 nm to 10 μm. The average particle size of ZnO powder is preferably from 40 nm to 5 μm. More preferably the average particle size of ZnO powder is preferably from 60 nm to 3 μm.

In another embodiment of the present invention, a conductive paste contains no ZnO powder. It was observed by the applicant that the conductive paste which contained no ZnO powder obtained superior contact resistance, as shown in the experimental section below.

### (Manufacturing Solar Cell Electrode)

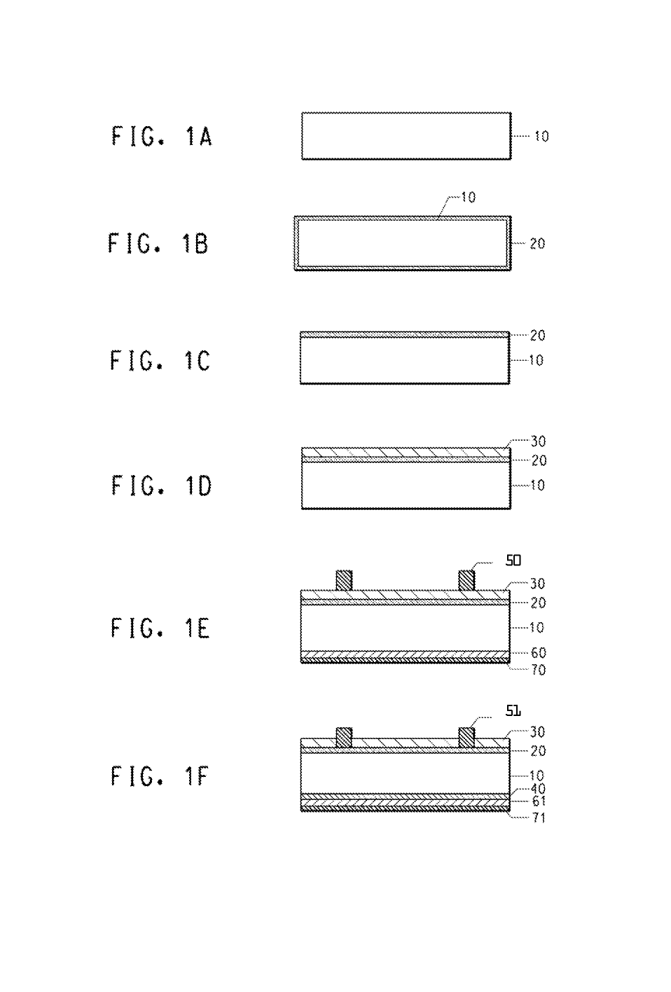

In an embodiment of the present invention, the electrode of the present invention can be used in a p-type base solar cell in which a p-type silicon layer is used as a base as shown in FIG. 1.

The following shows an embodiment of manufacturing process of a silicon type solar cell using the method for manufacturing a solar cell electrode of the present invention.

FIG. 1A shows a p-type silicon substrate 10.

In FIG. 1B, an n-layer 20, of the reverse conductivity type is formed by the thermal diffusion of phosphorus (P) or the like. Phosphorus oxychloride (POCl₃) is commonly used as the phosphorus diffusion source. In the absence of any particular modification, n-layer 20 is formed over the entire surface of the silicon substrate 10. The silicon wafer consists of p-type substrate 10 and n-layer 20 typically has a sheet resistivity on the order of several tens of ohms per square (ohm/□).

After protecting one surface of the n-layer with a resist or the like, the n-layer 20 is removed from most surfaces by etching so that it remains only on one main surface as shown in FIG. 1C. The resist is then removed using an organic solvent or the like. Next, a passivation layer 30 is formed on the n-layer 20 as shown in FIG. 1D by a process such as plasma chemical vapor deposition (CVD). SiNₓ, TiO₂, Al₂O₃, SiOₓ or ITO could be used as a material for a passivation layer. Most commonly used is Si₃N₄.

As shown in FIG. 1E, conductive paste 50 for the front electrode is screen printed then dried over the silicon nitride film which is the passivation layer 30. Aluminum paste, 60, and silver paste, 70, are screen printed onto the back side of the substrate, 10, and successively dried. The back side conductive layers may be two layers which comprise different metal respectively.

Firing is then carried out in an infrared furnace at a temperature range of 450° C. to 1000° C. Firing total time may be from 30 seconds to 5 minutes. At firing temperature of over 1000° C. or at a firing time of more than 5 minutes damage may occur to a semiconductor substrate.

In another embodiment of the present invention, firing profile may be 10-60 seconds at over 400° C. and 2-10 seconds at over 600° C. Firing peak temperature is preferably lower than 950° C. More preferably firing peak temperature is preferably lower than 800° C. In the present invention, less firing temperature is more preferable since the lower temperature would give less damage to a semiconductor substrate. Consequently a superior electrical property of a solar cell could be expected due to low firing temperature for forming a solar cell electrode.

As shown in FIG. 1F, during firing, aluminum diffuses as an impurity from the aluminum paste into the silicon substrate, 10, on the back side, thereby forming a p+ layer, 40, containing a high aluminum dopant concentration. Firing converts the dried aluminum paste, 60, to an aluminum back electrode, 61. The backside silver paste, 70, is fired at the same time, becoming a silver back electrode, 71. During firing, the boundary between the backside aluminum and the backside silver assumes the state of an alloy, thereby achieving electrical connection. Most areas of the back electrode are occupied by the aluminum electrode, partly on account of the need to form a p+ layer, 40. At the same time, because soldering to an aluminum electrode is not easy, the silver paste, 70, is used to form a backside electrode, 71, on limited areas of the backside as an electrode for interconnecting solar cells by means of copper ribbon or the like.

On the front side, the front electrode, 501, is made of the conductive paste, 500, of the present invention which is capable of fire through the passivation layer, 30, during firing to achieve electrical contact with the n-type layer, 20. The present invention may be used to form the front electrode, 501. This fired-through state, i.e., the extent to which the conductive paste on the front melts and passes through the passivation layer, 30, depends on the quality and thickness of the passivation layer, 30, composition of the conductive paste, 500, and on firing conditions. The conversion efficiency and moisture resistance reliability of the solar cell clearly depend, to a large degree, on this fired-through state.

In another embodiment of the present invention where the substrate has a passivation layer on the backside, the paste of the present invention can be applied as aluminum paste, 60, to form aluminum back electrode, 61. The paste can be applied as backside silver paste, 70, to form silver back electrode, 71. In another embodiment of the present invention where the substrate has a passivation layer on the backside, the paste of the present invention can be applied to a single-layer electrode on the backside. A paste for the single-layer electrode includes both of conductive powder and aluminum powder as conductive material.

Although the solar cell was the p-type base solar cell, in another embodiment of the present invention, the solar cell can be an n-type base solar cell.

Substrates, devices, methods of manufacture, and materials for the back contact type of a solar cell, which can be utilized with the conductive paste described herein are described in the following references. They are herein incorporated by reference.

J. E. Cotter et al., P-type versus n-type Silicon Wafers: Prospects for hi-efficiency commercial silicon solar cell; IEEE transactions on electron devices, VOL. 53, NO. 8, August 2006.

L. J. Geerligs, et al., N-TYPE SOLAR GRADE SILICON FOR EFFICIENT P+N SOLAR CELLS: OVERVIEW AND MAIN RESULTS OF THE EC NESSI PROJECT; European photovoltaic solar energy conference and exhibition 4-8 Sep. 2006.

In another embodiment, the solar cell can be a back contact type of solar cell. Substrates, devices, methods of manufacture, and materials for the back contact type of a solar cell, which can be utilized with the conductive paste described herein are described in US patent application publication numbers U.S. Pat. No. 7,959,831, US20080230119, which are hereby incorporated herein by reference.

The conductive paste comprising paste can be used to form a solar cell electrode wherever a solar cell electrode contacts with a semiconductor layer.

### EXAMPLES

The present invention is illustrated by, but is not limited to, the following examples.

### Example 1

### (Conductive Paste Preparation)

The conductive paste was produced using the following materials.

Conductive Powder: 100 parts by weight of silver powder was used. The shape was spherical. The particle diameter (D50) was 2.7 μm as determined with a laser scattering-type particle size distribution measuring apparatus.

Metal resinate: lead 2-ethylhexyl acid (CAS No.: 301-08-6), Lead content was 24 wt % of the lead resinate. Pb resinate was 1.3 parts by weight based on the 100 parts by weight of Ag powder. Accordingly, the content of lead in terms of parts by weight based on the 100 parts by weight of Ag powder was calculated by the following formula: Pb content=1.3 parts by weight×24 wt %=0.3 parts by weight.

Organic medium: Terpineol solution of ethyl cellulose.

Glass frit: 6 parts by weight of a borosilicate lead glass. Softening point was 440° C.

Conductive paste preparations were accomplished with the following procedure. Silver powder, the lead resinate and the glass frit were dispersed in the organic medium and mixed for 15 minutes. When well mixed, the paste was repeatedly passed through a 3-roll mill for at progressively increasing pressures from 0 to 400 psi. and the gap of the rolls was adjusted to 1 mil. The degree of dispersion was measured by fineness of grind (FOG). A typical FOG value was generally equal to or less than 20/10 for a conductor.

### (Manufacture of Test Pieces)

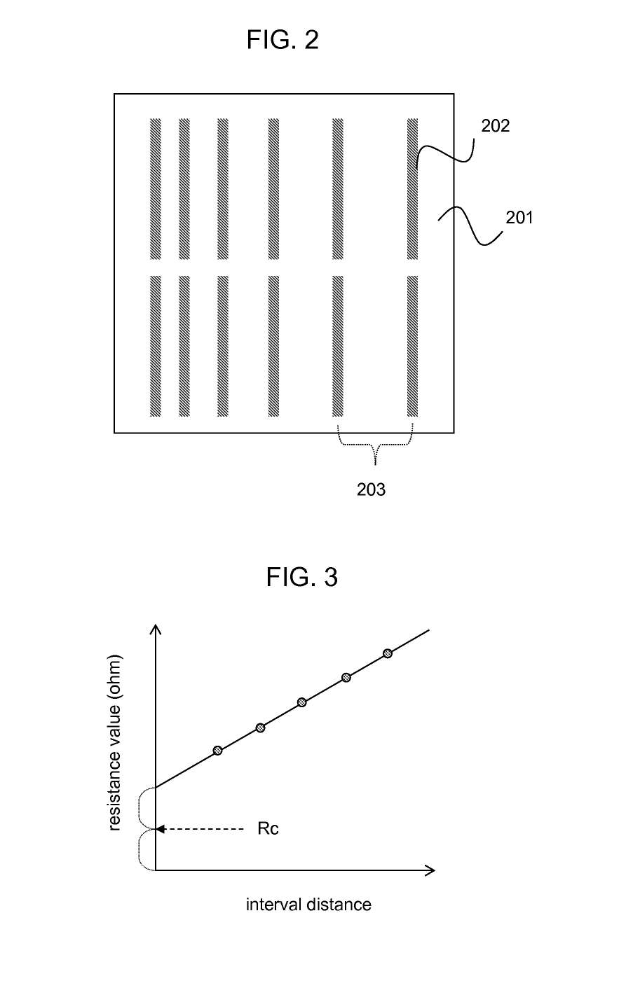

The conductive paste obtained by the above method was screen printed on a silicon wafer (38 mm×38 mm) 201 (FIG. 2). The silicon wafer had a passivation layer (SiNₓ) on one side surface of the wafer. The conductive paste was applied on the passivation layer. The printed pattern of electrodes 202 were line shape (10 mm width, 1 mm length and 15 μm thickness) as shown in FIG. 2. The interval distance between electrodes were 1 mm, 2 mm, 3 mm, 4 mm, and 5 mm respectively. The conductive paste on the wafer was dried at 150° C. for 5 min in a convection oven. Electrodes were then obtained upon being sintered in an IR heating type of belt furnace (CF-7210, Despatch industry) at varying peak temperature setting with 865° C. The belt speed during sintering was 370 cpm.

### (Measurement of Contact Resistance)

Contact Resistance (Rc) was calculated by Transmission Line Model (TLM) method with data measured with a source meter (2420, Keithley Instruments Inc.). Probes were put on between electrodes 202 to measure resistance between the electrodes by applying direct voltage. Rc calculation was as follows. Rc is a half value of Y-intercept of the line which can plot value of resistance in a graph with the resistance value (ohm) on the y-axis and the interval distance 203 between electrodes on the x-axis (FIG. 3).

### Example 2

An electrode was manufactured and Rc was measured by the same manner of example 1, except using a barium (Ba) resinate in place of the lead resinage.

The Ba resinate was Ba dilaurate (CAS No.: 4696-57-5), barium content was 25 wt % of the Ba resinate. The Ba resinate was 1.2 parts by weight based on the 100 parts by weight of Ag powder. Accordingly, parts by weight of Ba, based on the 100 parts by weight of Ag powder, was calculated by the following formula: Ba content=1.2 parts by weight×25 wt %=0.3 parts by weight.

### Example 3

An electrode was manufactured and Rc was measured by the same manner of example 1, except using a calcium (Ca) resinate in place of the lead resinage.

The Ca resinate was 2-ethylhexyl acid Ca (CAS No.: 136-51-6). Ca content was 5 wt % of the Ca resinate. The Ca resinate was 6.0 parts by weight based on the 100 parts by weight of Ag powder. Accordingly, Ca based on the 100 parts by weight of Ag powder was calculated by the following formula: Ba content=6.0 parts by weight×5 wt %=0.3 parts by weight.

### Example 4

An electrode was manufactured and Rc was measured by the same manner of example 1, except using a bismuth (Bi) resinate in place of the lead resinage.

The Bi resinate was 2-ethylhexyl acid Bi (CAS No.: 67874-71-9). Bi content was 25 wt % of the Bi resinate. The Bi resinate was 1.2 parts by weight based on the 100 parts by weight of Ag powder. Accordingly, Bi content was calculated by the following formula: Bi content=1.2 parts by weight×25 wt %=0.3 parts by weight.

### Comparative Example 1

An electrode was manufactured and Rc was measured by the same manner of example 1, except using a rhodium (Rh) resinate in place of the lead resinage.

The Rh resinate was Rh tris(2-ethylhexanoate) (CAS No.: 20845-92-5). Rh content was 10.0 wt % of the Rh resinate. The Rh resinate was 3.0 parts by weight based on the 100 parts by weight of Ag powder. Accordingly, Rh content was calculated by the following formula: Rh content=3 parts by weight×10 wt %=0.3 parts by weight.

### Comparative Example 2

An electrode was manufactured and Rc was measured by the same manner of example 1, except using no metal resinate in place of the lead resinage.

### (Results)

Contact resistance (Rc) in logarithmic conversion are shown in Table 1. In example 1 to 4, solar cell electrodes showed lower Rc. Comparative example 2 using no metal resinate had high Rc beyond the measurable range.

TABLE 1

| | Composition (parts by weight) | | | | |
|---|---|---|---|---|---|
| | | Glass | Metal of the | | |
| | Ag | frit | metal resinate | | Rc |
| Example 1 | 100 | 6 | Pb | 0.3 | 17.3 |
| Example 2 | 100 | 6 | Ba | 0.3 | 59.9 |
| Example 3 | 100 | 6 | Ca | 0.3 | 12.3 |
| Example 4 | 100 | 6 | Bi | 0.3 | 12.3 |
| Com. example 1 | 100 | 6 | Rh | 0.3 | 200 |
| Com. example 2 | 100 | 6 | None | 0 | —** |

*Too high to measure.

We claim:

1. A method for manufacturing a solar cell electrode, comprising:
applying onto a semiconductor substrate a conductive paste comprising a conductive powder, a glass frit, a metal resinate wherein a metal contained in the metal resinate is 0.15 to 1 parts by weight based on 100 parts by weight of the conductive powder and an organic medium; and
firing the conductive paste.

2. The method for manufacturing a solar cell electrode of claim 1, wherein the metal resinate is expressed by the following formula (I),
Me(XR)ₙ (I)
wherein Me is selected from the group consisting of lead (Pb), barium (Ba), calcium (Ca), bismuth (Bi), and a mixture thereof, X is selected from the group consisting of —O(CO)—, —(CO)O—, —CO—, —S—, and —SO₃—; R is selected from the group consisting of linear, branched and cyclic hydrocarbons having 1 to 10 carbon atoms, and n is 1, 2 or 3.

3. The method for manufacturing a solar cell electrode according to claim 1, wherein the metal resinate is 0.2 to 20 parts by weight, based on 100 parts by weight of the conductive powder.

4. The method for manufacturing a solar cell electrode according to claim 1, wherein the metal is Ca or Bi.

5. The method for manufacturing a solar cell electrode according to claim 1, wherein the conductive paste is applied on a passivation layer formed on the semiconductor substrate.

6. A conductive paste for forming a solar cell electrode, comprising:
a conductive powder;
a glass frit;
a metal resinate wherein a metal contained in the metal resinate is 0.15 to 1 parts by weight based on 100 parts by weight of the conductive powder; and
an organic medium.

7. The conductive paste for a solar cell of claim 6, wherein the metal resinate is expressed by the following formula (I),
Me(XR)ₙ (I)
wherein Me is selected from the group consisting of lead (Pb), barium (Ba), calcium (Ca), bismuth (Bi), and a mixture thereof, X is selected from the group consisting of —O(CO)—, —(CO)O—, —CO—, —S—, and —SO₃—, R is selected from the group consisting of linear, branched and cyclic hydrocarbons having 1 to 10 carbon atoms, and n is 1, 2 or 3.

8. The conductive paste for solar cell according to claim 6, wherein the metal resinate can be 0.2 to 20 parts by weight, based on 100 parts by weight of the conductive powder.

9. The conductive paste for solar cell according to claim 6, wherein the metal is Ca or Bi.

10. A solar cell electrode formed on the semiconductor substrate, wherein the electrode, prior to the firing, comprises the conductive paste of claim 6.
